(19) United States
(12) Patent Application Publication
(10) Pub. No.: US 2017/0151754 A1
(43) Pub. Date: Jun. 1, 2017

(54) OPTICAL MEMBER INCLUDING ANTIREFLECTION FILM AND METHOD OF MANUFACTURING THE SAME

(71) Applicant: FUJIFILM Corporation, Tokyo (JP)

(72) Inventors: Tatsuya YOSHIHIRO, Ashigarakami-gun (JP); Shinichiro SONODA, Ashigarakami-gun (JP)

(73) Assignee: FUJIFILM Corporation, Tokyo (JP)

(21) Appl. No.: 15/429,450

(22) Filed: Feb. 10, 2017

Related U.S. Application Data
(63) Continuation of application No. PCT/JP2015/003737, filed on Jul. 27, 2015.

(30) Foreign Application Priority Data
Aug. 27, 2014 (JP) 2014-172242
Sep. 26, 2014 (JP) 2014-196274

(51) Int. Cl. B32B 7/02; G02B 1/118; C23C 14/00; C23C 14/18; C23C 16/06; B32B 37/14

(52) U.S. Cl. CPC B32B 7/02; C23C 16/06; B32B 37/14; C23C 14/0036; C23C 14/185; G02B 1/118; B32B 2307/412; B32B 2307/418

(57) ABSTRACT

The optical member includes: a transparent substrate; and an antireflection film that is formed on surface, in which the antireflection film includes a fine unevenness layer and an interlayer, the fine unevenness layer includes an alumina hydrate as a major component and has a uneven structure having a shorter distance between convex portions than a wavelength of antireflection target light, the interlayer is disposed between the fine unevenness layer and the transparent substrate, a peak value of spatial frequency of the uneven structure in the fine unevenness layer is higher than 6.5 μm⁻¹, and the interlayer includes at least three layers alternately including a low refractive index layer and a high refractive index layer.

### CROSS-REFERENCE TO RELATED APPLICATIONS

This application is a Continuation of PCT International Application No. PCT/JP2015/003737 filed on Jul. 27, 2015, which claims priority under 35 U.S.C. §119(a) to Japanese Patent Application No. 2014-172242 filed on Aug. 27, 2014 and Japanese Patent Application No. 2014-196274 filed on Sep. 26, 2014. Each of the above applications is hereby expressly incorporated by reference, in its entirety, into the present application.

### BACKGROUND OF THE INVENTION

1. Field of the Invention

The present invention relates to an optical member having a surface on which an antireflection film is provided, and a method of manufacturing the same.

2. Description of the Related Art

In the related art, in a lens (transparent substrate) formed of a light-transmitting member such as glass or a plastic, an antireflection structure (antireflection film) is provided on a light incident surface in order to reduce loss of transmitted light caused by surface reflection.

For example, as an antireflection structure to visible light, for example, a dielectric multi-layer film or a fine uneven structure having a shorter pitch than a wavelength of visible light is known (for example, refer to JP2005-275372A and JP2013-33241A).

In general, the refractive index of a material constituting a fine uneven structure is different from that of a transparent substrate. Therefore, it is known that, in a case where a fine uneven structure is used for antireflection of a transparent substrate, means for matching a difference in refractive index between the antireflection structure and the transparent substrate is necessary.

JP2005-275372A discloses a configuration in which a fine unevenness layer is formed over a substrate with a transparent thin layer (interlayer) interposed therebetween. The unevenness layer includes an alumina hydrate as a major component, and the transparent thin layer includes at least one of zirconia, silica, titania, or zinc oxide.

In addition, as described in JP2013-33241A, a method of laminating first and second matching layers in this order from a substrate side is known, the two matching layers (interlayer) having a refractive index in a range of the refractive index of a thin layer to the refractive index of the substrate. In this method, specifically, a relationship of “refractive index of substrate>refractive index of first matching layer>refractive index of second matching layer>refractive index of fine unevenness layer” is satisfied.

### SUMMARY OF THE INVENTION

While conducting a strict investigation on an antireflection structure including a fine unevenness layer, the present inventors found that, in a case where a fine unevenness layer formed of an alumina hydrate is provided in an antireflection structure, light scattering occurs at a low but intolerable level and is recognized as fogging on an antireflection film-formed surface of a product such as a lens, which causes a problem in that there is a large effect on the quality of the optical element.

The present invention has been made in consideration of the above-described circumstances, and an object thereof is to provide an optical member including an antireflection film in which light scattering is prevented and in which sufficient antireflection performance is maintained.

The present inventors thought that, in an antireflection film which includes a fine unevenness layer formed of an alumina hydrate (boehmite), the reason for fogging is that a fine uneven structure is random. The fine uneven structure has a size of a wavelength or less of light and thus has little effect on light scattering. However, it is assumed that, in a case where there is a long-period fluctuation having about the size of a light wavelength, the fine uneven structure has an effect on light scattering. Based on this assumption, the present inventors performed a thorough investigation and found that a scattered light intensity has a correlation with a peak value of spatial frequency in the fine uneven structure, thereby completing the present invention.

That is, according to the present invention, there is provided a first optical member comprising: a transparent substrate; and an antireflection film that is formed on a surface of the transparent substrate, in which the antireflection film includes a fine unevenness layer and an interlayer, the fine unevenness layer includes an alumina hydrate as a major component and has a uneven structure having a shorter distance between convex portions than a wavelength of antireflection target light, the interlayer is disposed between the fine unevenness layer and the transparent substrate, a peak value of spatial frequency of the uneven structure in the fine unevenness layer is higher than 6.5 μm⁻¹, the interlayer includes a low refractive index layer and a high refractive index layer that are laminated in this order from the transparent substrate side, the low refractive index layer has a lower refractive index than a refractive index of the transparent substrate, and the high refractive index layer has a higher refractive index than the refractive index of the transparent substrate.

In this specification, “major component” is defined as a component whose content is 80 mass % or higher with respect to all the materials for forming a film.

That is, according to the present invention, there is provided a second optical member comprising: a transparent substrate; and an antireflection film that is formed on a surface of the transparent substrate, in which the antireflection film includes a fine unevenness layer and an interlayer, the fine unevenness layer includes an alumina hydrate as a major component and has a uneven structure having a shorter distance between convex portions than a wavelength of antireflection target light, the interlayer is disposed between the fine unevenness layer and the transparent substrate, a peak value of spatial frequency of the uneven structure in the fine unevenness layer is higher than 6.5 the interlayer includes three or more layers including a low refractive index layer and a high refractive index layer that are alternately laminated, the low refractive index layer has a lower refractive index than a refractive index of the transparent substrate, and the high refractive index layer has a higher refractive index than the refractive index of the transparent substrate.

It is preferable that the following conditions are satisfied:

1.45<n_{L}<1.8 and 1.6<n_{H}<2.4; and

8 nm<d_{L}<160 nm and 4 nm<d_{H}<16 nm,

where the refractive index of the low refractive index layer is represented by n_{L}, the thickness of the low refractive index layer is represented by d_{L}, the refractive index of the high refractive index layer is represented by n_{H}, and the thickness of the high refractive index layer is represented by d_{H}.

It is preferable that the fine unevenness layer includes, as a major component, an alumina hydrate which is obtained by performing a warm water treatment on aluminum.

It is preferable that the refractive index of the transparent substrate is higher than 1.65 and lower than 1.74, the low refractive index layer is formed of silicon oxide, and the high refractive index layer is formed of silicon-niobium oxide.

The refractive index of the transparent substrate may be higher than 1.65 and lower than 1.74, the low refractive index layer may be formed of silicon oxinitride, and the high refractive index layer may be formed of silicon-niobium oxide.

It is preferable that the refractive index of the fine unevenness layer changes in a thickness direction and has a maximum value at a point between the center of the fine unevenness layer in the thickness direction and an interface between the fine unevenness layer and the interlayer.

According to the present invention, there is a provided a method of manufacturing the above-described optical member, the method comprising: forming the interlayer on the transparent substrate; forming an aluminum film on an outermost surface of the interlayer; and forming the fine unevenness layer including an alumina hydrate as a major component by performing an warm water treatment on the aluminum film in pure water having an electrical resistivity of 10 MΩ·cm or higher.

In this specification, the electrical resistivity is a value measured at a water temperature of 25° C. The electrical resistivity can be measured using, for example, an electrical resistivity meter HE-200R (manufactured by Horiba Ltd.).

In the method of manufacturing the optical member according to the present invention, it is preferable that the interlayer and the aluminum film are formed using a vapor deposition method.

In the optical member according to the present invention, the antireflection film includes a fine unevenness layer and an interlayer, the fine unevenness layer includes an alumina hydrate as a major component and has a uneven structure having a shorter distance between convex portions than wavelength of antireflection target light, the interlayer is disposed between the fine unevenness layer and the transparent substrate, and a peak value of spatial frequency of the uneven structure in the fine unevenness layer is higher than 6.5 μm⁻¹. Therefore, the scattered light intensity can be further reduced as compared to a fine uneven structure of the related art having a peak value of spatial frequency of 6.5 μm⁻¹ or less.

In addition, the interlayer includes a low refractive index layer and a high refractive index layer that are laminated in this order from the transparent substrate side, the low refractive index layer has a lower refractive index than a refractive index of the transparent substrate, and the high refractive index layer has a higher refractive index than the refractive index of the transparent substrate. Therefore, the antireflection performance of the antireflection film is extremely high.

### BRIEF DESCRIPTION OF THE DRAWINGS

FIG. 1 is a schematic cross-sectional view showing a configuration of an optical member according to the present invention.

FIG. 2 is a diagram showing a refractive index distribution in a fine uneven structure according to the present invention.

FIG. 3 is a diagram showing SEM images and spatial frequency spectra.

FIG. 4 is a diagram showing a method of measuring a scattered light intensity.

FIG. 5 is a diagram showing a relationship between a peak value of spatial frequency and a scattered light amount.

FIG. 6 is a diagram showing the dependence of the reflectance on the wavelength in an optical member according to Example 1.

FIG. 7 is a diagram showing the dependence of the reflectance on the wavelength in an optical member according to Comparative Example 3.

FIG. 8 is a diagram showing the dependence of the reflectance on the wavelength in an optical member according to Example 2.

FIG. 9 is a diagram showing the dependence of the reflectance on the wavelength in an optical member according to Example 3.

FIG. 10 is a diagram showing the dependence of the reflectance on the wavelength in an optical member according to Example 4.

FIG. 11 is a diagram showing the dependence of the reflectance on the wavelength in an optical member according to Example 5.

FIG. 12 is a diagram showing the dependence of the reflectance on the wavelength in an optical member according to Example 6.

FIG. 13 is a diagram showing the dependence of the reflectance on the wavelength in an optical member according to Example 7.

FIG. 14 is a diagram showing the dependence of the reflectance on the wavelength in an optical member according to Example 8.

FIG. 15 is a diagram showing the dependence of the reflectance on the wavelength in an optical member according to Example 9.

FIG. 16 is a diagram showing the dependence of the reflectance on the wavelength in an optical member according to Example 10.

FIG. 17 is a diagram showing the results of a simulation regarding the dependence of the reflectance on the wavelength in an optical member according to Example 11.

FIG. 18 is a diagram showing the results of a simulation regarding the dependence of the transmittance on the wavelength in the optical member according to Example 11.

FIG. 19 is a diagram showing the results of measuring the dependence of the sum of the reflectance and the transmittance on the wavelength in each of optical members according to Examples 11 and 12.

FIG. 20 is a diagram showing the results of measuring the dependence of the reflectance on the wavelength in an optical member according to Example 13.

FIG. 21 is a diagram showing the results of measuring the dependence of the sum of the reflectance and the transmittance on the wavelength in the optical member according to Example 13.

### DESCRIPTION OF THE PREFERRED EMBODIMENTS

Hereinafter, an embodiment of the present invention will be described.

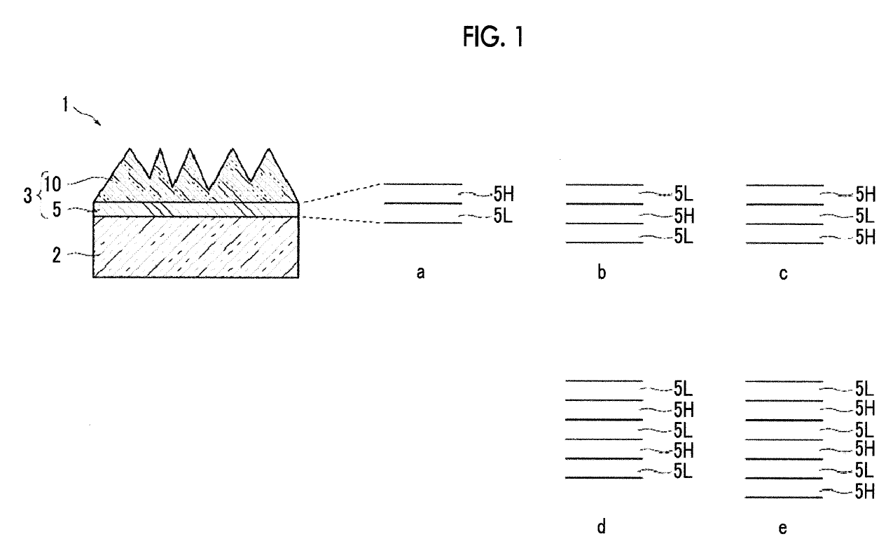

FIG. 1 is a cross-sectional view showing a schematic configuration of an optical member 1 according to the embodiment of the present invention. As shown in FIG. 1, the optical member 1 according to the embodiment includes: a transparent substrate 2; and an antireflection film 3 that is formed on a surface of the transparent substrate 2. The antireflection film 3 includes a fine unevenness layer 10 and an interlayer 5, the fine unevenness layer 10 includes an alumina hydrate as a major component and has a uneven structure having a shorter distance between convex portions than a wavelength of antireflection target light, and the interlayer 5 is disposed between the fine unevenness layer 10 and the transparent substrate 2.

The shape of the transparent substrate 2 is not particularly limited as long as the transparent substrate 2 can be used mainly in an optical element, and may be a flat plate, a concave lens, or a convex lens. In addition, the transparent substrate 2 may be a substrate which is obtained by combining a flat surface and a curved surface having a positive or negative curvature. As a material of the transparent substrate 2, for example, glass or a plastic can be used. Here, “transparent” represents that the substrate of the optical member is transparent to a wavelength of light (antireflection target light) as an antireflection target (the internal transmittance is substantially 10% or higher).

It is preferable that a refractive index n_{S} of the transparent substrate 2 is higher than 1.65 and lower than 1.74. Specific examples of a material satisfying the above conditions include S-NBH5 (manufactured by Ohara Inc.), S-LAL18 (manufactured by Ohara Inc.), MR-7 (manufactured by Mitsui Chemicals Inc.), MR-174 (manufactured by Mitsui Chemicals Inc.), general lanthanum glass, flint glass, a thiourethane resin, and an episulfide resin.

A peak value of spatial frequency of the uneven structure in the fine unevenness layer 10 is higher than 6.5 μm⁻¹. Examples of the alumina hydrate constituting the fine unevenness layer 10 include boehmite (represented by Al₂O₃.H₂O or AlOOH) which is alumina monohydrate, and bayerite (represented by Al₂O₃.3H₂O or Al(OH)₃) which is alumina trihydrate (aluminum hydroxide).

The fine unevenness layer 10 is transparent and has a substantially sawtooth-shaped cross-section although sizes (vertical angles) and orientations of convex portions vary. Distances between convex portions of the fine unevenness layer 10 are distances between peaks of most adjacent convex portions which separate concave portions from each other. The distances are shorter than or equal to the wavelength of the antireflection target light and are several tens of nanometers to several hundreds of nanometers. The distances are preferably 150 nm or shorter and more preferably 100 nm or shorter.

The average distance between convex portions can be obtained by obtaining a surface image of the fine uneven structure using a scanning electron microscope (SEM), processing the surface image to binarize image data, and performing a statistical procedure.

The uneven structure of the fine unevenness layer 10 has a random shape which causes light scattering in a case where there is a long-period fluctuation having about the size of a wavelength of light. The degree of the long-period fluctuation in the fine uneven structure can be estimated by Fourier transformation of a structure pattern. By performing discrete Fourier transform on an electron microscope image which is obtained by observing the fine uneven structure pattern from the top, the intensity spectrum of the spatial frequency can be calculated, and an intensity peak position thereof can be used as a reference of the structure size. The present inventors found that, as a peak wavelength of the spatial frequency increases, the scattered light intensity decreases. It was found that, in a case where the spatial frequency of the fine uneven structure is higher than 6.5 μm⁻¹, the occurrence of light scattering can be efficiently prevented (refer to Examples described below).

The fine unevenness layer 10 can be simply obtained by forming a thin film of a compound including aluminum as a precursor of the fine unevenness layer 10 and performing a warm water treatment of dipping the thin film of the compound including aluminum in warm water at 70° C. or higher for 1 minute or longer. In the present invention, it is preferable that the warm water treatment is performed after forming the aluminum film using a vapor deposition method such as vacuum deposition, plasma sputtering, electron cyclotron sputtering, or ion plating. The electrical conductivity of the warm water treatment liquid varies depending on factors such as contamination of a warm water treatment tank, gas absorption in air, or addition of additives. It is necessary to use ultrapure water having an electrical conductivity of 10 MΩ·cm or higher as a treatment raw material solution of the warm water treatment. In a case where pure water having an electrical resistivity of lower than 10 MΩ·cm is used as a raw material of the warm water treatment liquid, the peak of spatial frequency of the obtained fine uneven structure becomes lower than 6.5 μm⁻¹, and excellent light scattering properties cannot be obtained. On the other hand, in a case where the aluminum film is formed as the precursor of the fine uneveness layer and where pure water having an electrical resistivity of 10 MΩ·cm or higher is used as a raw material of the treatment liquid, the peak of spatial frequency of the obtained fine uneven structure becomes higher than 6.5 μm⁻¹, and excellent light scattering properties can be obtained.

The interlayer 5 includes a low refractive index layer 5L and a high refractive index layer 5H, the low refractive index layer 5L has a lower refractive index n_{L} than a refractive index n_{S} of the transparent substrate, and the high refractive index layer 5H has a higher refractive index n_{H} than the refractive index n_{S} of the transparent substrate. In a case where the interlayer 5 has a two-layer structure, as shown in a of FIG. 1, the low refractive index layer 5L and the high refractive index layer 5H are laminated in this order from the transparent substrate 2 side. On the other hand, in a case where the interlayer 5 includes three or more layers, the low refractive index layer 5L and the high refractive index layer 5H are alternately laminated. For example, in a case where the interlayer 5 includes three layers, the low refractive index layer 5L, the high refractive index layer 5H, and the low refractive index layer 5L may be laminated in this order from the transparent substrate 2 side as shown in b of FIG. 1, and the high refractive index layer 5H, the low refractive index layer 5L, and the high refractive index layer 5H may be laminated in this order from the transparent substrate 2 side as shown in c of FIG. 1. The interlayer 5 may include four or more layers, for example, a five-layer structure as shown in d of FIG. 1 or a six-layer structure as shown in e of FIG. 1. In a case where the interlayer includes three or more layers, when the low refractive index layer 5L and the high refractive index layer 5H are alternately laminated, any one of the layers may be laminated first from the transparent substrate 2 side.

In the interlayer 5, at least one low refractive index layer 5L is provided between the high refractive index layer 5H and the transparent substrate 2.

The low refractive index layer 5L only has to have the lower refractive index n_{L} than the refractive index n_{S} of the transparent substrate 2, and the high refractive index layer 5H only has to have the higher refractive index n_{H} than the refractive index n_{S} of the transparent substrate 2. In particular, it is preferable that 1.45<n_{L}<1.8 and 1.6<n_{H}<2.4.

In a case where plural low refractive index layers 5L are provided, the low refractive index layers 5L may not have the same refractive index. It is preferable that the low refractive index layers 5L are formed of the same material and have the same refractive index from the viewpoint of reducing the material costs, the film formation costs, and the like. Likewise, in a case where plural high refractive index layers 5H are provided, the high refractive index layers 5H may not have the same refractive index. It is preferable that the high refractive index layers 5H are formed of the same material and have the same refractive index from the viewpoint of reducing the material costs, the film formation costs, and the like.

Each of a thickness d_{L} of the low refractive index layer 5L and a thickness d_{H} of the high refractive index layer 5H may be determined based on a relationship between the refractive index and the reflected light wavelength and the like. It is preferable that 8 nm<d_{L}<160 nm and 4 nm<d_{H}<16 nm.

Examples of a material of the low refractive index layer 5L include silicon oxide, silicon oxinitride, gallium oxide, aluminum oxide, lanthanum oxide, lanthanum fluoride, and magnesium fluoride.

Examples of a material of the high refractive index layer 5H include niobium oxide, silicon-niobium oxide, zirconium oxide, tantalum oxide, silicon nitride, and titanium oxide.

It is preferable that the low refractive index layer 5L is formed silicon oxide and that the high refractive index layer 5H is formed of silicon-niobium oxide. It is preferable that the low refractive index layer 5L is formed silicon oxinitride and that the high refractive index layer 5H is formed of niobium oxide.

It is preferable that each of the layers of the interlayer 5 is formed using a vapor deposition method such as vacuum deposition, plasma sputtering, electron cyclotron sputtering, or ion plating. According to the vapor deposition method, a laminate structure which includes layers having various refractive indices and various thicknesses can be easily formed.

As described above in JP2005-275372A and JP2013-33241A, it is known that In the antireflection film which includes the fine unevenness layer formed of an alumina hydrate, in order to obtain excellent antireflection performance to glass materials having various refractive indices, an interlayer for adjusting optical interference is essential.

However, the present inventors found that light scattering occurs frequently in a fine uneven structure of the related art, and in a case where the fine uneven structure of the related art is applied to an optical element such as a lens, fogging occurs and optical properties are not sufficient. As a result of thorough investigation, the present inventors found that, a peak of spatial frequency in a fine uneven structure of the related art is about 6.5 μm⁻¹ or lower, and in a case where a peak of spatial frequency in a fine uneven structure has is 6.5 μm⁻¹ or lower, light scattering occurs at an intolerable level due to properties of the fine uneven structure.

The present inventors found that, by controlling the peak of spatial frequency in the fine uneven structure to be higher than 6.5 μm⁻¹ preferably 7 μm⁻¹ or higher, the occurrence of light scattering can be significantly reduced (refer to Examples described below).

On the other hand, as a result of investigation, it was found that: in a case where a fine unevenness layer having a peak of spatial frequency of 6.5 μm or lower is provided, sufficient antireflection properties can be obtained using one interlayer; and in a case where a fine unevenness layer formed of an alumina hydrate and having a peak of spatial frequency of higher than 6.5 μm⁻¹ is provided, sufficient antireflection properties cannot be obtained using one interlayer.

In addition, even in a case where an interlayer having a two-layer structure in which two layers are laminated such that the refractive index decreases in a direction from the substrate side to the fine unevenness layer side is used, excellent antireflection properties cannot be obtained.

A fine unevenness layer of the related art which is formed of an alumina hydrate has a refractive index profile in which the refractive index decreases in a thickness direction away from the substrate side. However, as a result of study, the present inventors found that, in the fine uneven structure used in the present invention having a peak of spatial frequency of higher than 6.5 μm⁻¹, the refractive index has a maximum value at a position between the center of the fine unevenness layer in the thickness direction and an interface between the fine unevenness layer and the interlayer.

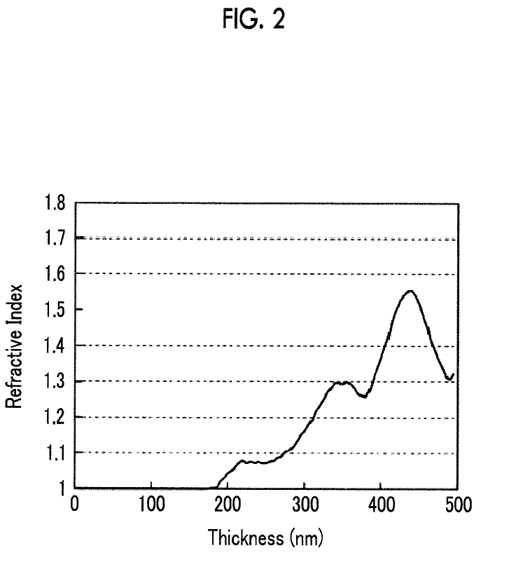

FIG. 2 shows a refractive index profile of a fine uneven structure having a peak of spatial frequency of 7.4 μm⁻¹. The refractive index distribution of the fine uneven structure was obtained by spectroscopic ellipsometry measurement and reflectance measurement.

In FIG. 2, a position where the refractive index 1 represents air, a position in a range of 180 nm to 490 nm in the horizontal axis represents the fine unevenness layer, a position of 180 nm in the horizontal axis represents a surface of the fine unevenness layer, and a position of 490 nm in the horizontal axis represents a surface of the fine unevenness layer on the substrate side (the interface between the fine unevenness layer and the interlayer). As shown in FIG. 2, in a case where the peak of spatial frequency is 7.4 μm⁻¹, the fine uneven structure has a refractive index profile in which the refractive index gradually increases from the surface side, has a maximum value at a position between the center of the fine unevenness layer in the thickness direction and an interface between the fine unevenness layer and the interlayer, and decreases to a value similar to the value before the peak in a range from the peak point to the interface.

A well-known fine unevenness layer of the related art which includes an alumina hydrate as a major component has a refractive index profile in which the refractive index monotonously increases from the surface side and has a maximum value at a interface position between the fine unevenness layer and an interlayer. It has not been known that the fine unevenness layer of the related art has the refractive index profile in which the peak of refractive index (maximum refractive index) is positioned between the center of the fine unevenness layer in the thickness direction and the interface between the fine unevenness layer and the interlayer and in which the refractive index at the interface between the fine unevenness layer and the interlayer is lower than the maximum peak by 10% or higher.

It is thought that, in the interlayer structure of the related art, sufficient antireflection properties cannot be obtained due to the above-described refractive index profile.

As described above, in the interlayer according to the present invention, the high refractive index layer and the low refractive index layer are alternately laminated. In a case where the interlayer has a two-layer structure, the low refractive index layer is disposed on the transparent substrate side. By using the interlayer 5 having the above-described configuration and the fine unevenness layer 10 which includes the fine uneven structure in which a peak of spatial frequency is higher than 6.5 μm⁻¹, the antireflection film 3 can achieve excellent antireflection properties.

As a result of further investigation, the present inventors found that, in a case where the high refractive index layer 5H of the interlayer 5 is formed of niobium oxide or silicon-niobium oxide, when an aluminum film as a precursor of the fine unevenness layer is formed in contact with the film formed of niobium oxide or silicon-niobium oxide during the warm water treatment, the occurrence of light scattering increases significantly in the formed antireflection film, and the transmittance decreases significantly.

The reason for this is thought to be that a reaction between Nb₂O₅ and water inhibits a conversion reaction of aluminum into an alumina hydrate (so-called boehmite conversion) at some positions. Therefore, in a case where a niobium oxide layer or a silicon-niobium oxide layer is used as the high refractive index layer of the interlayer, it is preferable that a cap layer is provided between the aluminum film and the niobium oxide layer or the silicon-niobium oxide layer such that the aluminum film is not in direct contact with the niobium oxide layer or the silicon-niobium oxide layer. The cap layer only has to be formed of a material which does not inhibit the warm water reaction of aluminum. From the viewpoint of the material costs and the like, it is preferable that the low refractive index layer is a thin film formed of silicon oxinitride and silicon oxide and having a thickness of 10 nm or less.

### EXAMPLES

Hereinafter, Examples of the present invention and Comparative Examples will be described, and the configurations and effects of the present invention will be described in detail.

First, optical members including antireflection films according to Example 1 of the present invention and Comparative Examples 2 and 3 were prepared, and the results of investigating a relationship between the spatial frequency and scattered light amount will be described.

### Example 1

A silicon oxinitride layer (refractive index n_{L}=1.552, thickness: 69.6 nm) as the low refractive index layer of the interlayer and a niobium oxide layer (refractive index n_{H}=2.351, thickness: 5.0 nm) as the high refractive index layer of the interlayer were laminated in this order on a substrate S-NBH5 (manufactured by Ohara Inc.; refractive index n_{S}=1.659), and an aluminum thin film having a thickness of 40 nm was formed on the niobium oxide layer. Next, the laminate was dipped in warm water. As a result, a fine unevenness layer including an alumina hydrate as a major component and having a transparent fine uneven structure was prepared, and an optical member according to Example 1 was obtained.

Here, the silicon oxinitride layer and the niobium oxide layer were formed by reactive sputtering, and the A1 thin film was formed by RF sputtering. In the warm water treatment, the laminate was dipped in warm water heated to 100° C. for 3 minutes. In this example, as a warm water treatment liquid, ultrapure water having an electrical resistivity of 12 MΩ·cm was used.

### Comparative Example 1

Using the method of Example 1, an alumina (Al₂O₃) thin film was formed by reactive sputtering instead of forming the aluminum thin film. As a warm water treatment liquid, pure water having an electrical resistivity of 8 MΩ·cm was used. An optical member according to Comparative Example 1 was obtained using the same method as in Example 1, except for the above-described configurations.

### Comparative Example 2

Using the method of Example 1, an alumina (Al₂O₃) thin film was formed by reactive sputtering instead of forming the aluminum thin film. An optical member according to Comparative Example 2 was obtained using the same method as in Example 1, except for conditions of the interlayer and the warm water treatment.

Regarding each of Example 1 and Comparative Examples 1 and 2, the electrical resistivity of water which is a raw material of the warm water treatment liquid was measured at a water temperature of 25° C. using an electrical resistivity meter HE-200R (manufactured by Horiba Ltd.).

Regarding each of the fine uneven structures of the fine unevenness layers of the optical members according to Example 1 and Comparative Examples and 1 and 2, a scattered light amount and a peak value of spatial frequency were obtained.

The peak value of spatial frequency was obtained as described below. An electron microscope image (magnification: 30000, acceleration voltage: 7.0 kV) obtained using a scanning electron microscope S-4100 (manufactured by Hitachi Ltd.) was cut into a size of 600×400 pixels and underwent two-dimensional Fourier transformation using an image processing software Igor. A square intensity spectrum of the obtained two-dimensional spatial frequency was calculated in an azimuth angle, and a spectral intensity corresponding to the size of the spatial frequency was obtained. As a result, a relationship between the one-dimensional spatial frequency and the spectral strength was calculated. The peak value of the spectrum was obtained by fitting the vicinity of the peak to Lorentz function using the image processing software Igor.

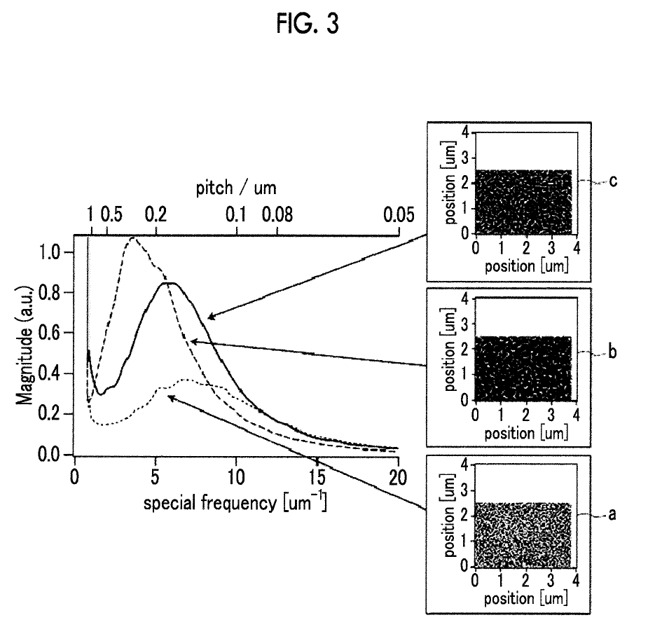

FIG. 3 is a diagram showing electron microscope images a to c and spatial frequency spectra of Example 1 and Comparative Examples 1 and 2.

As shown in FIG. 3, a peak of spatial frequency of 7.4 μm⁻¹ was obtained from the image a of the fine uneven surface of the optical member according to Example 1, a peak of spatial frequency of 3.7 μm⁻¹ was obtained from the image b of the fine uneven surface of the optical member according to Comparative Example 1, and a peak of spatial frequency of 5.9 μm⁻¹ was obtained from the image c of the fine uneven surface of the optical member according to Comparative Example 2.

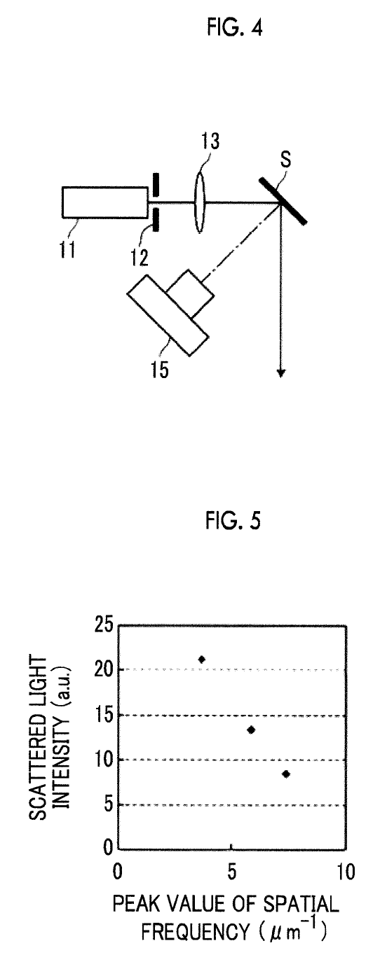

FIG. 4 is a schematic diagram showing a method of measuring a scattered light intensity. The scattered light intensity was measured in the following procedure.

In FIG. 4, regarding a sample S representing the surface of the fine unevenness layer of each of the optical members according to Example 1 and Comparative Examples 1 and 2, light emitted from an Xe lamp light source 11 was narrowed by an iris 12 having an aperture of 3 mm and was collected on the sample S at an incidence angle of 45° using a collecting lens 13 of f=100 mm. Using a digital still camera Fine pix S3 pro (manufactured by Fujifilm Corporation) 15 on which a lens (manufactured by Fujifilm Corporation) having a focal length f of 85 mm and an F value of 4.0 was mounted, the sample surface was imaged under conditions of ISO speed: 200 and shutter speed: 1/2 sec. The average of pixel values in a light collecting region of 128×128 pixels was obtained as a scattered light amount.

FIG. 5 is a graph showing a relationship between the peak of spatial frequency and the scattered light amount which were obtained by the above-described measurements.

In addition, Table 1 shows the film forming conditions, the spatial frequency, and the scattered light amount in each of Example 1 and Comparative Examples 1 and 2.

TABLE 1

| | Material of | Electrical | | |
|---|---|---|---|---|
| | Aluminum- | Resistivity of | | |
| | Containing | Warm Water | Peak Value | Scattered |
| | Film: | Treatment | of Spatial | Light |
| | Thickness | Liquid | Frequency | Amount |
| | [nm] | [MΩ · cm] | [μm⁻¹] | [a.u.] |
| Example 1 | Al: 40 | 12 | 7.4 | 8.5 |
| Comparative | Al₂O₃: 65 | 8 | 3.7 | 21.2 |
| Example 1 | | | | |
| Comparative | Al₂O₃: 65 | 12 | 5.9 | 13.4 |
| Example 2 | | | | |

As shown in FIG. 5, it was found that, as the peak value of spatial frequency increases, the scattered light amount decreases. It can be seen from FIG. 5 that the peak value of spatial frequency is necessarily higher than 6.5 μm⁻¹ in order to control the scattered light amount to be 15 or lower. In addition, by controlling the peak value of spatial frequency to be 7 μm⁻¹ or higher, further reduction in the scattered light amount can be expected.

As shown in Example 1, by using aluminum as a material of the aluminum-containing film and performing the warm water treatment in which ultrapure water having an electrical resistivity of 12 MΩ·cm was used, a fine uneven structure having a high peak value of spatial frequency was obtained. On the other hand, as shown in Comparative Example 2, in a case where alumina was used as a material of the aluminum-containing film even when the same ultrapure water as in Example 1 was used, the peak value of spatial frequency of the fine uneven structure obtained after the warm water treatment was 5.9 μm⁻¹, and a reduction in the scattered light amount was not sufficient.

Even in a case where a fine uneven structure was formed using an aluminum film and pure water having an electrical resistivity of about 8 MΩ·cm, the peak value of spatial frequency of the fine uneven structure is substantially equal to that of Comparative Example 2, and a reduction in the scattered light amount was not sufficient.

Next, the results of measuring antireflection properties regarding each of the optical member according to Examples of the present invention and Comparative Examples will be described.

Regarding each of Example 1 described above and Comparative Example 3 and Examples 2 to 10 described below, antireflection properties were measured using a spectroscopic reflectometer for film thickness FE-3000 (manufactured by Otsuka Electronics Co., Ltd.).

Table 2 shows a layer configuration, a refractive index of each layer, and a thickness thereof in Example 1. In Table 2, A1 described as the outermost layer represents the layer as the precursor of the fine unevenness layer, and the thickness thereof was measured before the warm water treatment. In addition, the thickness of each of the layers was set and each of the refractive index layers was formed under sputtering conditions which were set in consideration of the relationship between the film thickness and the sputtering time and the relationship between the composition ratio and the like and the refractive index, the sputtering conditions including the sputtering time and the oxygen flow rate for obtaining the thickness and the designed refractive index, and the like. The same shall be applied to Tables 3 to 13.

TABLE 2

| Example 1 | Refractive Index | Thickness [nm] |
|---|---|---|
| Al | — | 40 |
| Niobium Oxide | 2.351 | 5.0 |
| Silicon Oxinitride | 1.552 | 69.6 |
| Transparent Substrate | 1.659 | — |

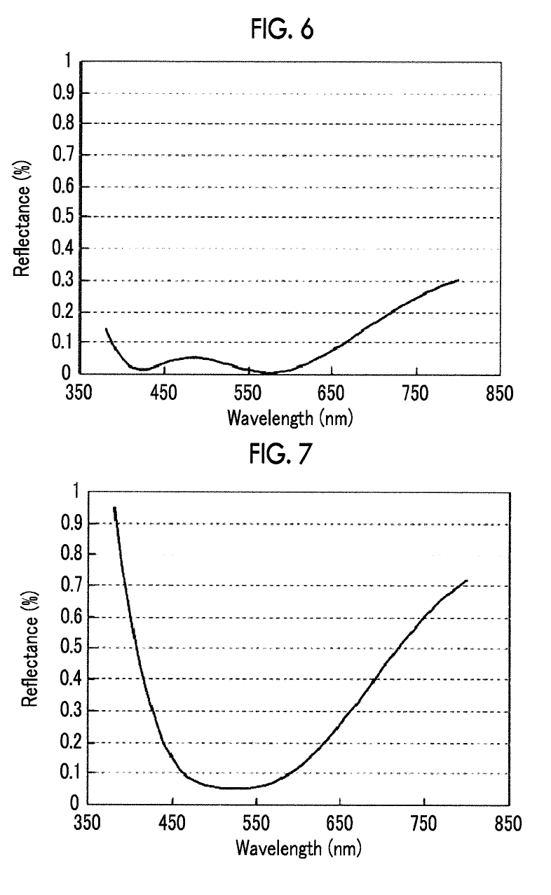

FIG. 6 shows the dependence of the reflectance on the wavelength in Example 1.

As shown in FIG. 6, the reflectance of Example 1 was 0.1% or lower in a wavelength range of 400 nm to 660 nm, and the reflection properties as an optical element were significantly favorable.

### Comparative Example 3

An optical member according to Comparative Example 3 was prepared using the same method as in Example 1, except that conditions of the refractive indices and thicknesses of the interlayer were changed as shown in Table 3.

TABLE 3

| Comparative Example 3 | Refractive Index | Thickness [nm] |
|---|---|---|
| Al | — | 40 |
| Silicon Oxinitride | 1.552 | 107.7 |
| Transparent Substrate | 1.659 | — |

FIG. 7 shows the dependence of the reflectance on the wavelength in Comparative Example 3.

As shown in FIG. 7, the reflectance of Comparative Example 3 was 0.1% only in a wavelength range of 460 nm to 600 nm, and reflection properties were not favorable.

### Example 2

An optical member according to Example 2 was prepared using the same method as in Example 1, except that conditions of the refractive indices and thicknesses of the interlayer were changed as shown in Table 4.

TABLE 4

| Example 2 | Refractive Index | Thickness [nm] |
|---|---|---|
| Al | — | 40 |
| Niobium Oxide | 2.351 | 1.0 |
| Silicon Oxinitride | 1.55 | 107.8 |
| Transparent Substrate | 1.659 | — |

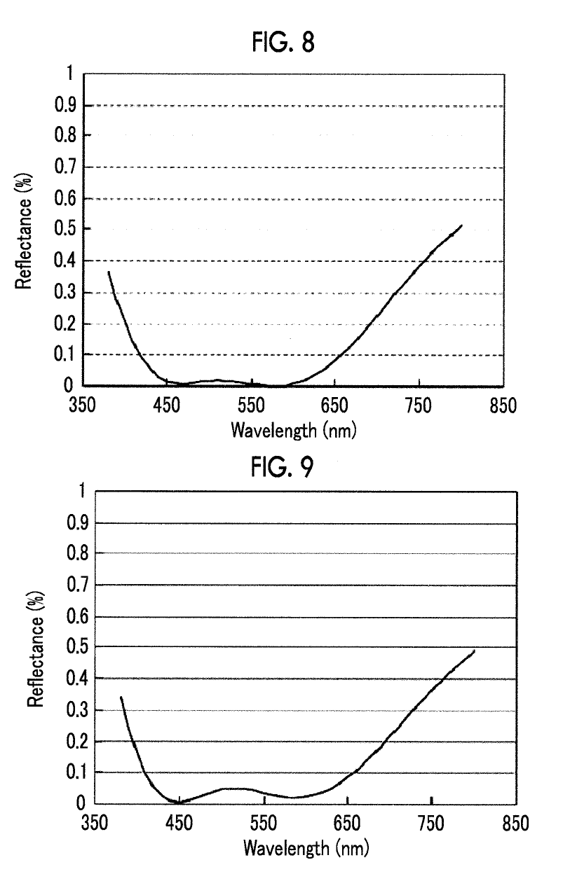

FIG. 8 shows the dependence of the reflectance on the wavelength in Example 2.

As shown in FIG. 8, the reflectance of Example 2 was 0.1% or lower in a wavelength range of 420 nm to 650 nm, and the reflection properties as an optical element were significantly favorable.

### Example 3

An optical member according to Example 3 was prepared using the same method as in Example 1, except that conditions of the refractive indices and thicknesses of the interlayer were changed as shown in Table 5.

TABLE 5

| Example 3 | Refractive Index | Thickness [nm] |
|---|---|---|
| Al | — | 40 |
| Niobium Oxide | 2.351 | 3.0 |
| Silicon Oxinitride | 1.552 | 99.8 |
| Transparent Substrate | 1.659 | — |

FIG. 9 shows the dependence of the reflectance on the wavelength in Example 3.

As shown in FIG. 9, the reflectance of Example 3 was 0.1% or lower in a wavelength range of 420 nm to 650 nm, and the reflection properties as an optical element were significantly favorable.

### Example 4

An optical member according to Example 4 was prepared using the same method as in Example 1, except that conditions of the refractive indices and thicknesses of the interlayer were changed as shown in Table 6.

TABLE 6

| Example 4 | Refractive Index | Thickness [nm] |
|---|---|---|
| Al | — | 40 |
| Niobium Oxide | 2.351 | 9.0 |
| Silicon Oxinitride | 1.521 | 39.4 |
| Transparent Substrate | 1.659 | — |

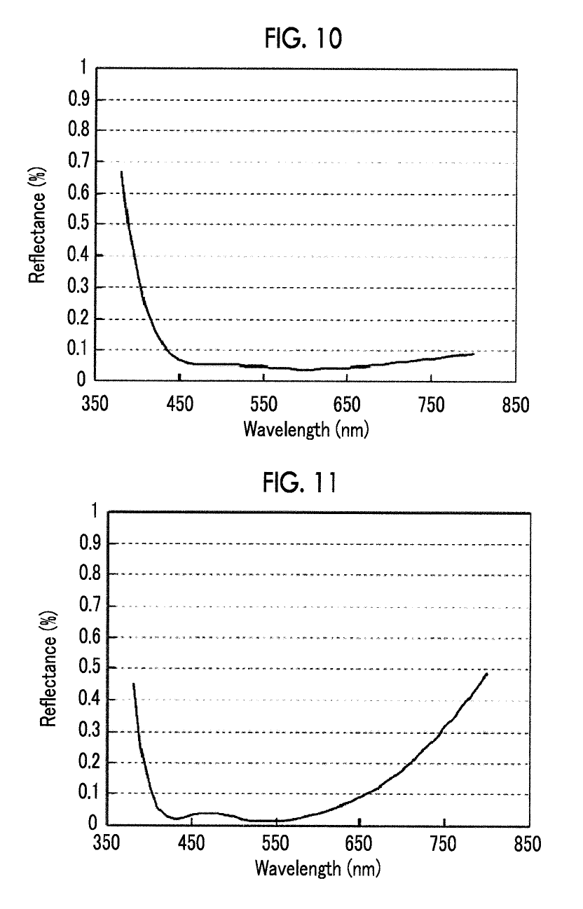

FIG. 10 shows the dependence of the reflectance on the wavelength in Example 4.

As shown in FIG. 10, the reflectance of Example 4 was 0.1% or lower in a wavelength range of 440 nm to 800 nm, and the reflection properties as an optical element were significantly favorable.

### Example 5

An optical member according to Example 5 was prepared using the same method as in Example 1, except that conditions of the refractive indices and thicknesses of the interlayer were changed as shown in Table 7.

TABLE 7

| Example 5 | Refractive Index | Thickness [nm] |
|---|---|---|
| Al | — | 40 |
| Silicon Oxinitride | 1.515 | 137.2 |
| Niobium Oxide | 2.351 | 5.0 |
| Silicon Oxinitride | 1.515 | 35.2 |
| Transparent Substrate | 1.659 | — |

FIG. 11 shows the dependence of the reflectance on the wavelength in Example 5.

As shown in FIG. 11, the reflectance of Example 5 was 0.1% or lower in a wavelength range of 420 nm to 650 nm, and the reflection properties as an optical element were significantly favorable.

### Example 6

An optical member according to Example 6 was prepared using the same method as in Example 1, except that conditions of the refractive indices and thicknesses of the interlayer were changed as shown in Table 8.

TABLE 8

| Example 6 | Refractive Index | Thickness [nm] |
|---|---|---|
| Al | — | 40 |
| Niobium Oxide | 2.351 | 5.0 |
| Silicon Oxinitride | 1.545 | 97.8 |
| Niobium Oxide | 2.351 | 5.0 |
| Silicon Oxinitride | 1.545 | 37.6 |
| Transparent Substrate | 1.659 | — |

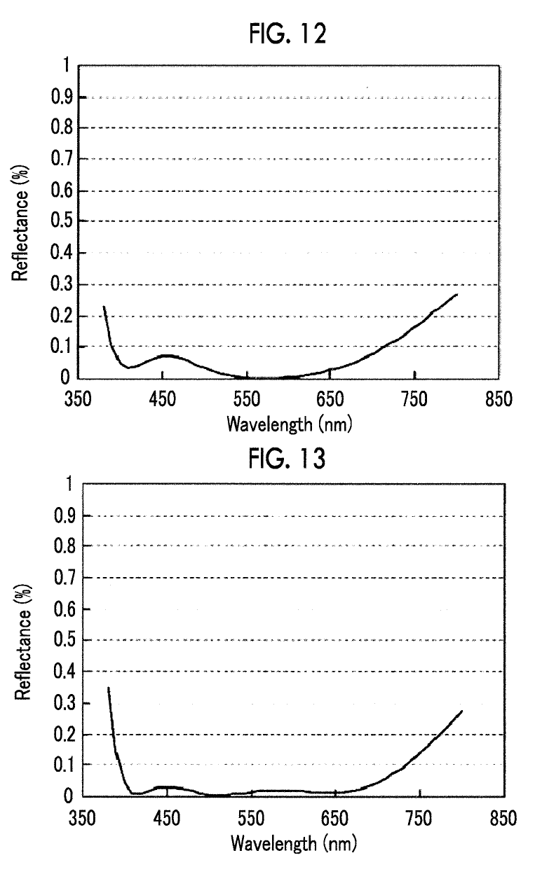

FIG. 12 shows the dependence of the reflectance on the wavelength in Example 6.

As shown in FIG. 12, the reflectance of Example 6 was 0.1% or lower in a wavelength range of 400 nm to 700 nm, and the reflection properties as an optical element were significantly favorable.

### Example 7

An optical member according to Example 7 was prepared using the same method as in Example 1, except that conditions of the refractive indices and thicknesses of the interlayer were changed as shown in Table 9.

TABLE 9

| Example 7 | Refractive Index | Thickness [nm] |
|---|---|---|
| Al | — | 40 |
| Silicon Oxinitride | 1.505 | 10.0 |
| Niobium Oxide | 2.351 | 6.0 |
| Silicon Oxinitride | 1.505 | 84.5 |
| Niobium Oxide | 2.351 | 6.0 |
| Silicon Oxinitride | 1.505 | 39.6 |
| Transparent Substrate | 1.659 | — |

FIG. 13 shows the dependence of the reflectance on the wavelength in Example 7.

As shown in FIG. 13, the reflectance of Example 7 was 0.1% or lower in a wavelength range of 400 nm to 730 nm, and the reflection properties as an optical element were significantly favorable.

### Example 8

A silicon oxide layer (refractive index=1.475, thickness: 30.4 nm) as the low refractive index layer of the interlayer and a film of a mixture of silicon oxide and niobium oxide, that is, a silicon-niobium oxide layer (refractive index=2.004, thickness: 15.6 nm) as the high refractive index layer of the interlayer were laminated in this order on a substrate S-LAL18 (manufactured by Ohara Inc.; refractive index n_{S}=1.733), and an aluminum thin film having a thickness of 40 nm was formed on the silicon-niobium oxide layer. Here, the film of the mixture of silicon oxide and niobium oxide was formed by meta-mode sputtering.

Next, the same warm water treatment as in Example 1 was performed, and an optical member according to Example 8 was obtained.

Table 10 shows a layer configuration, a refractive index of each layer, and a thickness thereof in Example 8.

TABLE 10

| Example 8 | Refractive Index | Thickness [nm] |
|---|---|---|
| Al | — | 40 |
| Silicon-Niobium Oxide | 2.004 | 15.6 |
| Silicon Oxide | 1.475 | 30.4 |
| Transparent Substrate | 1.733 | — |

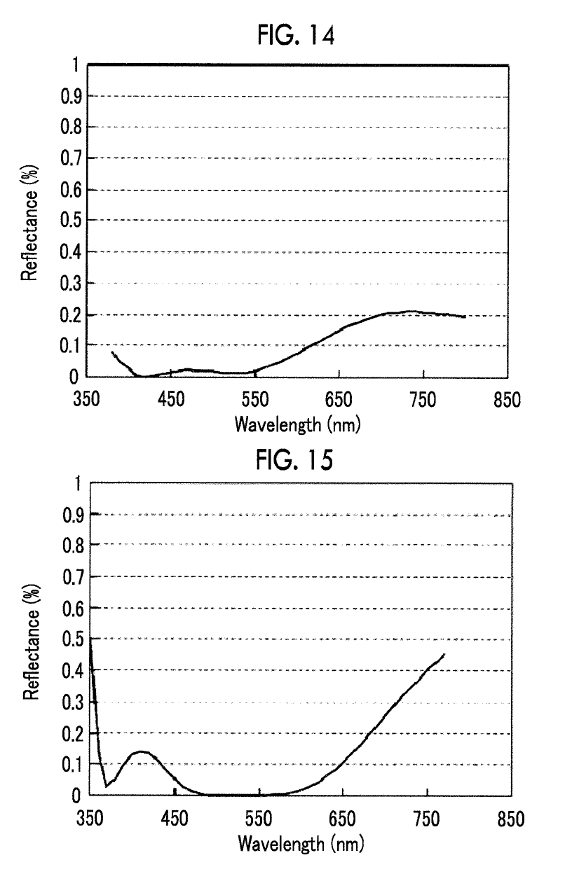

FIG. 14 shows the dependence of the reflectance on the wavelength in Example 8.

As shown in FIG. 14, the reflectance of Example 8 was 0.1% or lower in a wide and relatively low wavelength range of 370 nm to 620 nm, and the reflection properties as an optical element were significantly favorable.

### Example 9

An optical member according to Example 9 was prepared using the same method as in Example 1, except that conditions of the refractive indices and thicknesses of the interlayer were changed as shown in Table 11.

TABLE 11

| Example 9 | Refractive Index | Thickness [nm] |
|---|---|---|
| Al | — | 40 |
| Silicon-Niobium Oxide | 2.351 | 7.4 |
| Silicon Oxinitride | 1.505 | 56.4 |
| Silicon-Niobium Oxide | 2.351 | 3.0 |
| Transparent Substrate | 1.659 | — |

FIG. 15 shows the dependence of the reflectance on the wavelength in Example 9.

As shown in FIG. 15, the reflectance of Example 9 was 0.1% or lower in a wavelength range of 440 nm to 650 nm, and the reflection properties as an optical element were significantly favorable.

### Example 10

An optical member according to Example 10 was prepared using the same method as in Example 1, except that conditions of the refractive indices and thicknesses of the interlayer were changed as shown in Table 12.

TABLE 12

| Example 10 | Refractive Index | Thickness [nm] |
|---|---|---|
| Al | — | 40 |
| Silicon Oxinitride | 1.521 | 10.0 |
| Silicon-Niobium Oxide | 2.351 | 6.0 |
| Silicon Oxinitride | 1.521 | 77.1 |
| Silicon-Niobium Oxide | 2.351 | 9.0 |
| Silicon Oxinitride | 1.521 | 51.6 |
| Silicon-Niobium Oxide | 2.351 | 6.0 |
| Transparent Substrate | 1.659 | — |

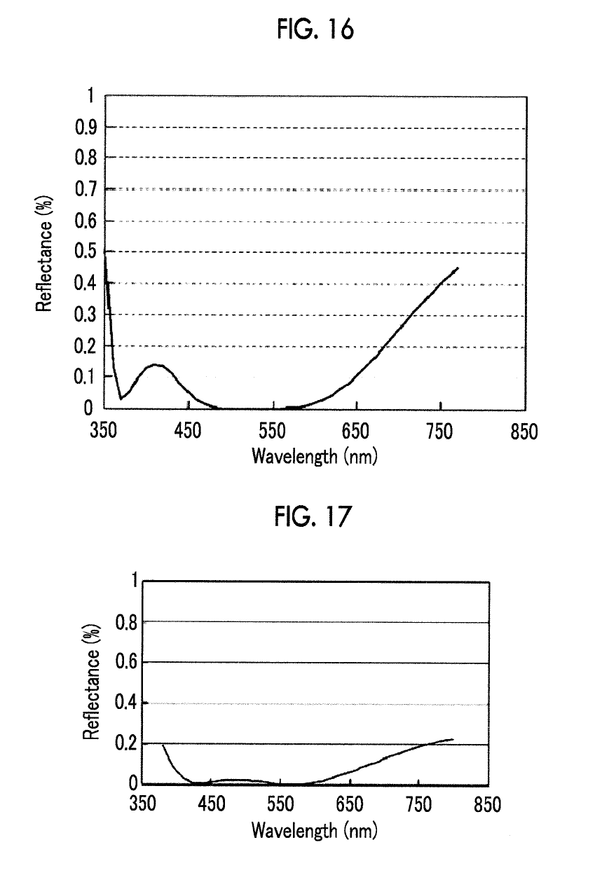

FIG. 16 shows the dependence of the reflectance on the wavelength in Example 10.

As shown in FIG. 16, the reflectance of Example 10 was 0.1% or lower in a wavelength range of 440 nm to 650 nm, and the reflection properties as an optical element were significantly favorable.

As described above, it is obvious that, in all the Examples 1 to 10 of the present invention, the reflectance is 0.1% or lower in a wavelength range of 200 nm or higher, and high antireflection performance can be achieved.

Further, the results of investigating the transmittance of the optical member including the antireflection film in which the high refractive index layer of the interlayer was formed of niobium oxide will be described.

### Example 11

A silicon oxinitride layer (refractive index=1.52837, thickness: 49.5 nm) as the low refractive index layer of the interlayer and a niobium oxide layer (refractive index=2.3508, thickness: 7 nm) as the high refractive index layer of the interlayer were laminated in this order on a substrate S-NBH5 (manufactured by Ohara Inc.; refractive index nS=1.6588), and an aluminum thin film having a thickness of 40 nm was formed on the niobium oxide layer. Next, the same warm water treatment as in Example 1 was performed, and an optical member according to Example 11 was obtained.

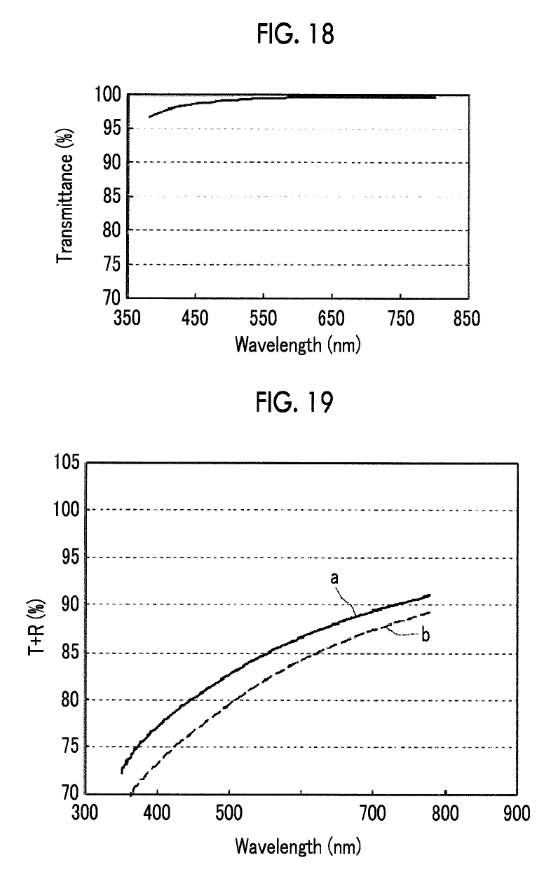

First, simulations were performed regarding the dependence of the reflectance of the antireflection film on the wavelength and the dependence of the transmittance of the antireflection film on the wavelength in the optical member according to Example 11. FIGS. 17 and 18 show the results of the simulations. The simulations were performed using a software Essential Macleod (Thin Film Center Inc.).

As shown in FIG. 17, in the results of the simulation, a profile similar to the dependence of the reflectance on the wavelength in Example 1 was obtained, and a wavelength of 0.1% was obtained in a wavelength range of 400 nm to 660 nm. In addition, as shown in FIG. 18, according to the simulation, the transmittance was extremely high, which was 96% or higher in the entire measurement region and was 99% or higher in a wavelength region of 550 nm or higher.

FIG. 19 shows the results of measuring the dependence of the sum (T+R) of the transmittance T and the reflectance R on the wavelength in Example 11. The dependence of T+R on the wavelength was measured using a spectrophotometer U-4000 (manufactured by Hitachi High-Technologies Corporation).

FIG. 19 also shows the dependence of the transmittance on the wavelength in Example 12 which was prepared using the same method as in Example 11, except that the thickness of the niobium oxide layer was changed to 5 nm. In FIG. 19, a solid line a represents the transmittance of Example 12, and a broken line b represents the transmittance of Example 11.

In the simulation, Example 11 shows an extremely high transmittance as shown in FIG. 18. However, in the measurement results regarding the optical member according to Example 11, as shown in FIG. 19, T+R was lower than 90% in the entire wavelength region. As the wavelength decreased, T+R decreased and was lower than 80% at 500 nm. It is thought that as the scattered light intensity increased, the transmittance decreased.

### Example 13

An optical member according to Example 13 including five layers was prepared, the five layers having a configuration in which the low refractive index layer and the high refractive index layer, which were formed of the silicon oxinitride layer and the niobium oxide layer, respectively, as described in Example 11, were alternately laminated and in which the fifth low refractive index layer as a layer immediately below the fine unevenness layer, which was formed of the silicon oxinitride layer and had a thickness of about 10 nm, was provided a cap layer. Regarding the optical member according to Example 13, the dependence of the reflectance on the wavelength and the dependence of T+R on the wavelength were measured.

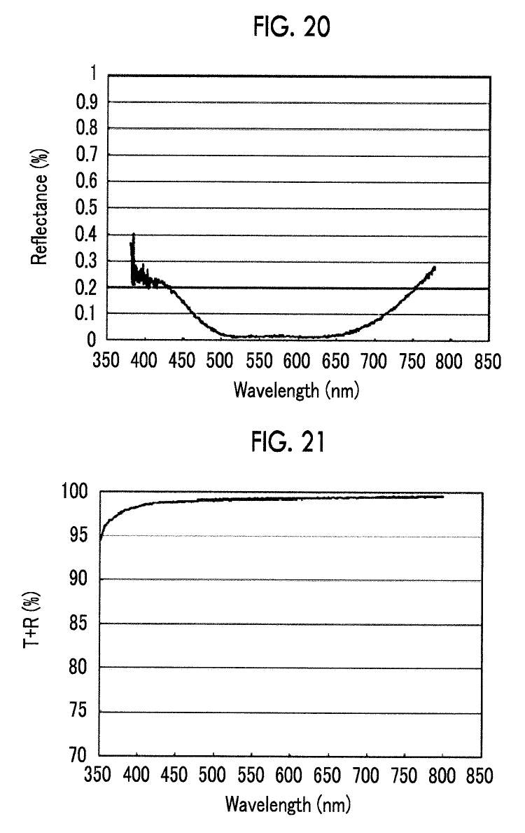

Table 13 shows the layer configuration of Example 13, FIG. 20 shows the dependence of the reflectance on the wavelength in Example 13, and FIG. 21 shows the dependence of T+R on the wavelength.

TABLE 13

| Example 13 | Refractive Index | Thickness [nm] |
|---|---|---|
| Al | — | 40 |
| Silicon Oxinitride | 1.521 | 10.0 |
| Silicon-Niobium Oxide | 2.351 | 6.0 |
| Silicon Oxinitride | 1.521 | 76.95 |
| Silicon-Niobium Oxide | 2.351 | 6.0 |
| Silicon Oxinitride | 1.521 | 36.93 |
| Transparent Substrate | 1.659 | — |

As shown in FIG. 20, in the optical member according to Example 13, the reflectance was 0.1% or lower in a wavelength range of 460 nm to 710 nm, and antireflection properties were favorable. Concurrently, as shown in FIG. 21, favorable results were able to be obtained, in which T+R was 98% or higher in a wavelength range of 450 nm to 800 nm, and the scattered light intensity was significantly low.

What is claimed is:

1. An optical member comprising:
a transparent substrate; and
an antireflection film that is formed on a surface of the transparent substrate,
wherein the antireflection film includes a fine unevenness layer and an interlayer,
the fine unevenness layer includes an alumina hydrate as a major component and has a uneven structure having a shorter distance between convex portions than a wavelength of antireflection target light,
the interlayer is disposed between the fine unevenness layer and the transparent substrate,
a peak value of spatial frequency of the uneven structure in the fine unevenness layer is higher than 6.5 μm⁻¹,
the interlayer includes at least three layers including a low refractive index layer and a high refractive index layer that are alternately laminated in this order from the transparent substrate side,
the low refractive index layer has a lower refractive index than a refractive index of the transparent substrate, and
the high refractive index layer has a higher refractive index than the refractive index of the transparent substrate.

2. The optical member according to claim 1,
the following conditions are satisfied:
1.45<n_{L}<1.8 and 1.6<n_{H}<2.4; and
8 nm<d_{L}<160 nm and 4 nm<d_{H}<16 nm,
where the refractive index of the low refractive index layer is represented by n_{L}, the thickness of the low refractive index layer is represented by d_{L}, the refractive index of the high refractive index layer is represented by n_{H}, and the thickness of the high refractive index layer is represented by d_{H}.

3. The optical member according to claim 1,
wherein the fine unevenness layer includes, as a major component, an alumina hydrate which is obtained by performing a warm water treatment on aluminum.

4. The optical member according to claim 1,
wherein the refractive index of the transparent substrate is higher than 1.65 and lower than 1.74,
the low refractive index layer is formed of silicon oxide, and
the high refractive index layer is formed of silicon-niobium oxide.

5. The optical member according to claim 2,
wherein the refractive index of the transparent substrate is higher than 1.65 and lower than 1.74,
the low refractive index layer is formed of silicon oxide, and
the high refractive index layer is formed of silicon-niobium oxide.

6. The optical member according to claim 3,
wherein the refractive index of the transparent substrate is higher than 1.65 and lower than 1.74,
the low refractive index layer is formed of silicon oxide, and
the high refractive index layer is formed of silicon-niobium oxide.

7. The optical member according to claim 1,
wherein the refractive index of the transparent substrate is higher than 1.65 and lower than 1.74,
the low refractive index layer is formed of silicon oxinitride, and
the high refractive index layer is formed of niobium oxide.

8. The optical member according to claim 2,
wherein the refractive index of the transparent substrate is higher than 1.65 and lower than 1.74,
the low refractive index layer is formed of silicon oxinitride, and
the high refractive index layer is formed of niobium oxide.

9. The optical member according to claim 3,
wherein the refractive index of the transparent substrate is higher than 1.65 and lower than 1.74,
the low refractive index layer is formed of silicon oxinitride, and
the high refractive index layer is formed of niobium oxide.

10. The optical member according to claim 1,
wherein the refractive index of the fine unevenness layer changes in a thickness direction and has a maximum value at a position between the center of the fine unevenness layer in the thickness direction and an interface between the fine unevenness layer and the interlayer.

11. The optical member according to claim 2,
wherein the refractive index of the fine unevenness layer changes in a thickness direction and has a maximum value at a position between the center of the fine unevenness layer in the thickness direction and an interface between the fine unevenness layer and the interlayer.

12. The optical member according to claim 3,
wherein the refractive index of the fine unevenness layer changes in a thickness direction and has a maximum value at a position between the center of the fine unevenness layer in the thickness direction and an interface between the fine unevenness layer and the interlayer.

13. The optical member according to claim 4,
wherein the refractive index of the fine unevenness layer changes in a thickness direction and has a maximum value at a position between the center of the fine unevenness layer in the thickness direction and an interface between the fine unevenness layer and the interlayer.

14. The optical member according to claim 7,
wherein the refractive index of the fine unevenness layer changes in a thickness direction and has a maximum value at a position between the center of the fine unevenness layer in the thickness direction and an interface between the fine unevenness layer and the interlayer.

15. A method of manufacturing the optical member according to claim 1, the method comprising:
forming the interlayer on the transparent substrate;
forming an aluminum film on an outermost surface of the interlayer; and
forming the fine unevenness layer including an alumina hydrate as a major component by performing an warm water treatment on the aluminum film in pure water having an electrical resistivity of 10 MΩ·cm or higher.

16. The method of manufacturing the optical member according to claim 15,
wherein the interlayer and the aluminum film are formed using a vapor deposition method.
